(19) United States
(12) Patent Application Publication
(10) Pub. No.: US 2025/0169379 A1
(43) Pub. Date: May 22, 2025

(54) QUANTUM DEVICE AND ASSOCIATED METHOD FOR MANUFACTURING

(71) Applicant: COMMISSARIAT A L'ENERGIE ATOMIQUE ET AUX ENERGIES ALTERNATIVES, PARIS (FR)

(72) Inventor: Benoit BERTRAND, GRENOBLE CEDEX (FR)

(21) Appl. No.: 18/954,945

(22) Filed: Nov. 21, 2024

(30) Foreign Application Priority Data
Nov. 21, 2023 (FR) 2312792

(51) Int. Cl. H10N 60/10; B82Y 10/00; G06N 10/40; H10N 60/01

(52) U.S. Cl. CPC H10N 60/128; G06N 10/40; H10N 60/01; H10N 60/11; B82Y 10/00

(57) ABSTRACT

A quantum device includes a semiconductor layer adapted to form a two-dimensional array of quantum dots, the semiconductor layer having a front face, a dielectric, disposed on the front face of the semiconductor layer, first gates and second gates to control the quantum dots, the first gates and the second gates extending directly over the dielectric, each second gate intersecting the first gates, charge detectors, each charge detector including a conductive island, and a charge reservoir, the conductive island of each charge detector being formed between two adjacent first gates and directly over the dielectric.

### CROSS-REFERENCE TO RELATED APPLICATIONS

This application claims priority to French Patent Application No. 2312792, filed Nov. 21, 2023, the entire content of which is incorporated herein by reference in its entirety.

### TECHNICAL FIELD OF THE INVENTION

The technical field of the invention is that of quantum electronics, and more particularly quantum electronic devices and the manufacture thereof.

### TECHNOLOGICAL BACKGROUND OF THE INVENTION

The use of quantum states at two measurable levels as information vectors, also referred to as “qubits” for “quantum bits”, and the laws of quantum mechanics (superposition, entanglement, measurement) offers the possibility of developing quantum algorithms that outperform some classes of conventionally used algorithms. To implement them, thousands of qubits are required. Finally, three types of operation have to be able to be performed on the qubits: initialisation in a known state, manipulation (logic gates on one or more qubits), and reading these qubits.

Semiconductor technologies capable of manipulating qubits comprise islands, also referred to as quantum dots, produced in nanometric confinement structures defined, for example, electrostatically within a semiconductor layer. Quantum dots ensure confinement of elementary charges, i.e. electrons or holes, and the quantum information is coded on the spin of these particles, for example.

For a quantum dot to be functional, i.e. for it to be initialised, manipulated and read, it has to be coupled to read electronics capable of determining the number of charges in the quantum dot.

The use of additional devices coupled to read electronics, such as charge detectors measured in current or reflectometry, enables charge number detection to be more effective than in-situ detection methods.

Single electron transistors (SET) are among the most efficient charge detectors.

In general, a SET comprises a quantum dot, or island, two charge reservoirs, also referred to as drain and source, and a gate contact.

The island is connected to each of the reservoirs by at least a tunnel junction, or tunnel coupling, electrostatically defined.

The charge reservoirs (drain and source) are considered to be bulk metallic materials whose electrons obey the Fermi-Dirac statistics, and the island is, for example, a metal grain a few nanometres in size. The gate contact is typically separated from the island by a layer of dielectric material. The tunnel junction is, for example, formed by another layer of dielectric material, referred to as a tunnel junction, arranged so as to separate the island from the charge and the gate contact.

One or more electrodes are additionally connected to the charge reservoirs and the gate contact to apply a voltage to these elements.

SETs work by capacitive coupling with the quantum dot, a fluctuation in the number of charges in the quantum dot, for example, modifying conduction of the SET and therefore being able to be measured.

This detection, or reading, of the resulting charge is generally carried out by current (in transport) or by reflectometry with the use of an LC resonator.

When the SET is read by current, its drain and source are polarized independently of each other. In other words, two independent charge reservoirs (source and drain) are required.

When the SET is read by reflectometry, there is no need for a static current to pass therethrough. Its drain and source are therefore polarizable to the same potential, and a single charge reservoir (drain or source) is sufficient. In this case, the SET, which is no longer quite equivalent to a transistor, is also referred to as a “Single Lead Quantum Dot” (SLQD).

Integrating SETs as close as possible to the qubits would be advantageous for improving detection sensitivity and saving space needed to implement qubit control functionalities.

However, SETs are expensive in terms of overall size due to the large number of elements that make them up. Their integration in the qubit plane reduces the number of qubits that can be integrated per unit area, and requires longer-range interactions between neighbouring qubits.

To overcome this difficulty, it is suggested to integrate the SETs at the periphery of the qubit array. The drawback is that the size of this array need to be reduced to a few quantum dots per side to enable the qubits disposed in the centre of the array to be read.

It is additionally suggested integrating and connecting charge detectors in planes different from the plane comprising the quantum dots. In this case this is referred to as circuits with a non-planar architecture, also referred to as “3D” for “3-dimensional”.

Patent application FR 3 066 297 thus provides a parallel-control quantum electronic circuit comprising a semiconductor layer receiving an array of qubits, a network of electrodes disposed on either side of this semiconductor layer, and a plane stacked on the semiconductor layer comprising an array of charge detectors.

This solution has the advantage that each charge detector is located in proximity to a qubit, whatever the qubit considered in the array.

However, the architecture of this circuit is particularly complex, due in particular to the high density of vias and interconnections. Hence, some manufacturing steps can be difficult to perform.

Thus, there is currently no satisfactory solution for integrating SETs into high-density 2D quantum electronic circuits.

There is thus still a need for a solution of integrating reflectometry-measured charge detectors into arrays of two-dimensional quantum dots, which allows good capacitive coupling between these charge detectors and the quantum dots while being simple to implement.

### SUMMARY OF THE INVENTION

The present invention offers a solution to the problems previously discussed by making it possible to reduce the overall size and complexity of reflectometry-read charge detectors on the chip.

More particularly, a first aspect of the invention provides a quantum device comprising:
a semiconductor layer adapted to form a two-dimensional array of quantum dots, the semiconductor layer having a front face,
a dielectric, disposed on the front face of the semiconductor layer,
first gates and second gates to control the quantum dots, the first gates and second gates extending directly over the dielectric, each second gate intersecting the first gates, the first and second gates defining a network of two-dimensional meshes, each two-dimensional mesh facing a quantum dot,
charge detectors, each charge detector comprising a conductive charge reservoir and a conductive island, the conductive island of each charge detector being formed at the level of a two-dimensional mesh, between two adjacent first gates and directly over the dielectric.

Thus, advantageously according to the invention, the conductive island of each charge detector is formed at the same level as that of the first and second gates (the term “same level” here means in the level included between a lower face of the first gates and an upper face of the second gates). This makes it possible to obtain a compact quantum device (in terms of height). It also makes it possible to obtain a quantum device that uses a single semiconductor substrate and whose manufacture does not involve bonding steps.

In addition, by virtue of the conductive island that is laid on the dielectric in a two-dimensional mesh, there is good capacitive coupling between the quantum dot formed in vertical alignment with the two-dimensional mesh and neighbouring quantum dots. This proximity improves detection sensitivity of the quantum device. It is appropriate to add that forming the conductive islands between first gates offers the advantage of being able to use these first gates as an alignment reference at the time of manufacturing the conductive islands. In other words, the first gates enable the islands to “self-align”. This self-alignment facilitates these manufacturing steps.

The quantum device according to the invention thus offers an integration solution compatible with industrial manufacturing methods and large-scale quantum dot integration, as well as providing the required proximity between the current-read charge detectors and the quantum dots.

Further to the characteristics just discussed in the preceding paragraph, the quantum device according to the first aspect of the invention may have one or more complementary characteristics from among the following, considered individually or according to any technically possible combinations:
each charge detector comprises a gate terminal, said gate terminal being formed by a barrier layer covering the conductive island corresponding to the charge detector.
the conductive island of each charge detector is formed in a gate for controlling the quantum dots distinct from the first gates, said gate intersecting the first gates and extending directly over the dielectric, said gate having recesses covered with an electrically insulating layer, the insulating recesses being disposed at the intersections of said gate with the first gates, each insulating recess accommodating a first gate, the insulating recesses defining in said gate a plurality of lower conductive regions extending directly over the dielectric, and a continuous upper conductive region.
said gate is one of the second gates.
Alternatively, said gate is a third gate in a set of third gates for controlling chemical potential of the quantum dots, each third gate being disposed in vertical alignment with the quantum dots formed along a column or diagonal of the array of quantum dots.
whatever said gate, said gate has an inner structure of a first type comprising:
   every other lower conductive region extending from the upper conductive region towards the dielectric and defines a complementary lower conductive region,
   the complementary lower conductive region covered with a lower barrier layer, referred to as a tunnel layer, the tunnel layer being disposed over the insulating recesses adjacent to the complementary lower conductive region,
   a dielectric pattern forming an upper barrier layer extending through the upper conductive region of the tunnel layer to the upper face of said gate, the dielectric pattern being coated with the upper conductive region and disposed in vertical alignment with at least part of the complementary lower conductive region.
a second gate out of two, or a third gate out of two, can then have the inner structure of the first type.
the conductive islands are then disposed staggered relative to each other.
Alternatively, each second gate, or each third gate, can have the inner structure of the first type.
Alternatively, said gate has an inner structure of a second type in which:
   all the lower conductive regions of said gate are covered with a tunnel layer, the tunnel layer being continuous and disposed on the recesses of said gate,
   each lower conductive region has a dielectric pattern, thereabove, each dielectric pattern forming with the tunnel layer a barrier layer, each dielectric pattern passing through the upper conductive region of the tunnel layer disposed on the associated lower conductive region to the upper face of said gate, the dielectric pattern being coated with the upper conductive region and disposed in vertical alignment with at least part of the associated lower conductive region.
a second gate out of two, or a third gate out of two, can then have the inner structure of the second type.
alternatively, each second gate, or each third gate, can have the inner structure of the second type.
the upper region of said gate can be coupled to a voltage source to address the sources of the charge detectors formed in said gate.
each dielectric pattern can extend, above from said gate, to a conductive via, referred to as the gate via.
the quantum device may comprise control rows of the charge detectors, each row being coupled to gate vias disposed on a same row of the array of quantum dots and, on the other hand, to a voltage source.
The quantum device can comprise metallisation rows, referred to as read rows of the charge detectors, each read row being coupled, on the one hand, to the upper region of a gate defining conductive islands and, on the other hand, to a read circuit, said read circuit comprising an inductance and a capacitance forming a resonant circuit whose resonant frequency depends on the impedance of the charge detectors, enabling reflectometry measurements.
each read row couples conductive portions located on a same row of the array of quantum dots, or couples conductive portions located on a same diagonal of the array of quantum dots.
the semiconductor layer comprises holes to form quantum dots,
the holes are disposed in vertical alignment with the meshes of the network of two-dimensional meshes defined by the first and second gates.
The island of each charge detector being located in a same horizontal plane than the first lines of gates, and the charge reservoir of each charge detector being located in a same horizontal plane than an upper conductive region of the second lines of gates.

A second aspect of the invention relates to a method for manufacturing a quantum device comprising charge detectors, each charge detector comprising a conductive island and a charge reservoir, the method comprising the following steps of:
providing a semiconductor layer adapted to form a two-dimensional array of quantum dots, said semiconductor layer having a front face, said semiconductor layer comprising a dielectric disposed on the front face and first gates to control the quantum dots, the first gates extending directly over the dielectric,
coating the flanks and upper face of each first gate to house each first gate under an insulating recess,
defining conductive islands from the first coated gates, each conductive island extending between two adjacent first gates and directly over the dielectric,
forming, from the conductive islands defined, second gates to control, with the first gates, the quantum dots, each second gate extending directly over the dielectric and intersecting the first gates, the first and second gates forming a network of two-dimensional meshes on the dielectric.

Preferably, the conductive island definition step may comprise the following sub-steps of:
filling, with a conductive material, the spaces of the dielectric which are delimited by two adjacent first gates coated, filling stopping at the insulating recesses,
forming a barrier layer over the entire surface after filling,
structuring the barrier layer to form barrier strips oriented at a predetermined angle relative to the first gates.

Preferably, the predetermined angle is such that the barrier strips are oriented at 45° relative to the direction of the first gates, the barrier strips extending, in the direction perpendicular to the first gates, over four adjacent conductive strips.

The invention and its different applications will be better understood upon reading the following description and upon examining the accompanying figures.

### BRIEF DESCRIPTION OF THE FIGURES

The figures are set forth by way of indicating and are in no way limiting purposes of the invention.

FIG. 1 shows a schematic representation in a top view of a quantum device according to one embodiment of the invention,

FIG. 2 shows a schematic representation in a cross-section view of the quantum device represented in FIG. 1,

FIG. 3 shows a schematic representation of part of the quantum device shown in FIG. 2,

FIG. 4 shows a schematic representation in a perspective view of part of the quantum device represented in FIG. 1,

FIG. 5 shows a schematic representation in a top view of a quantum device alternative to the quantum device represented in FIG. 1, for forming as many charge detectors as quantum dots,

FIG. 6 shows a schematic representation in a cross-section view of the quantum device represented in FIG. 5,

FIG. 7 schematically represents a top view of an alternative quantum device to the quantum device represented in FIG. 1, for positioning the charge detectors in vertical alignment with the quantum dots,

FIG. 8 schematically represents a top view of a quantum device alternative to the quantum device represented in FIG. 7,

FIG. 9 shows a first schematic representation in a cross-section view of the quantum device represented in FIG. 8,

FIG. 10 is a block diagram illustrating the sequence of steps of a method for manufacturing the quantum device represented in FIG. 1,

FIGS. 11A to 11L illustrate steps or sub-steps of the method for manufacturing represented in FIG. 10, each figure showing a perspective view and a cross-section view of the quantum device made during one of the steps or sub-steps,

FIG. 12 shows a schematic representation in a cross-section view of the quantum device according to an embodiment of the invention.

Unless otherwise specified, a same element appearing in different figures has a single reference.

### DETAILED DESCRIPTION

The present invention is within the context of quantum electronic devices as well a method for manufacturing the same. More particularly, the invention aims to enable, via reflectometry-read charge detectors, efficient detection of the state of charge of quantum dots formed on the quantum devices. Still in particular, the invention aims to reduce space occupied by these charge detectors on the quantum device in order to provide an architecture for making large-scale spin qubits.

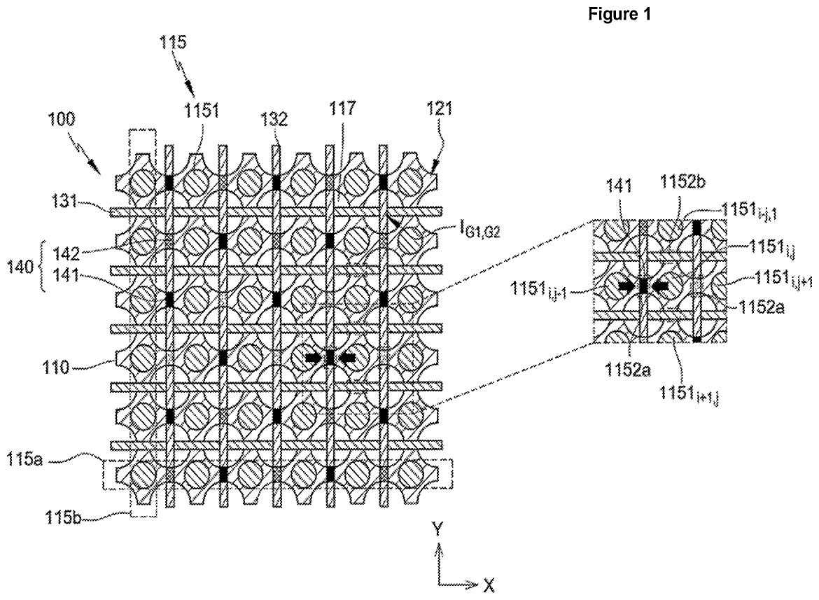

FIGS. 1, 2, 3 and 4 schematically represent a quantum device 100 according to a first embodiment.

FIG. 1 schematically shows a top view of part of the quantum device 100 according to this first embodiment.

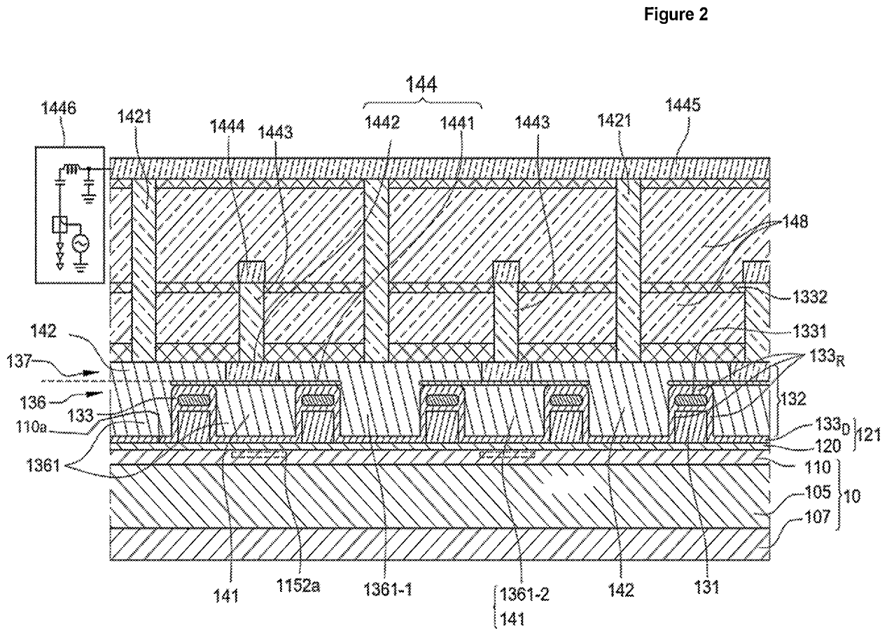

FIGS. 2 to 4 show different views of a first alternative embodiment of the quantum device 100 represented in FIG. 1.

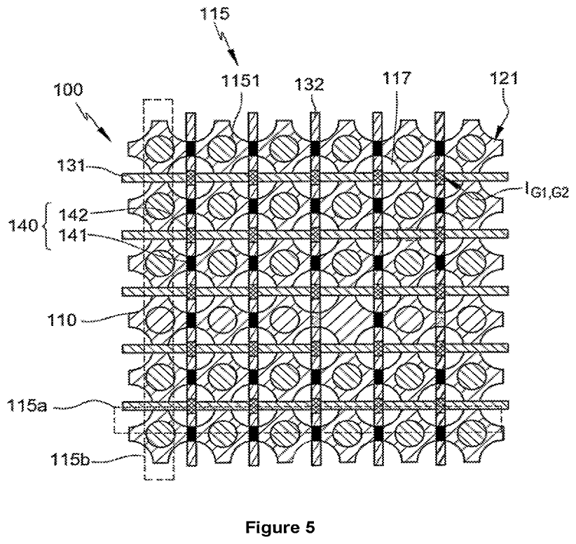

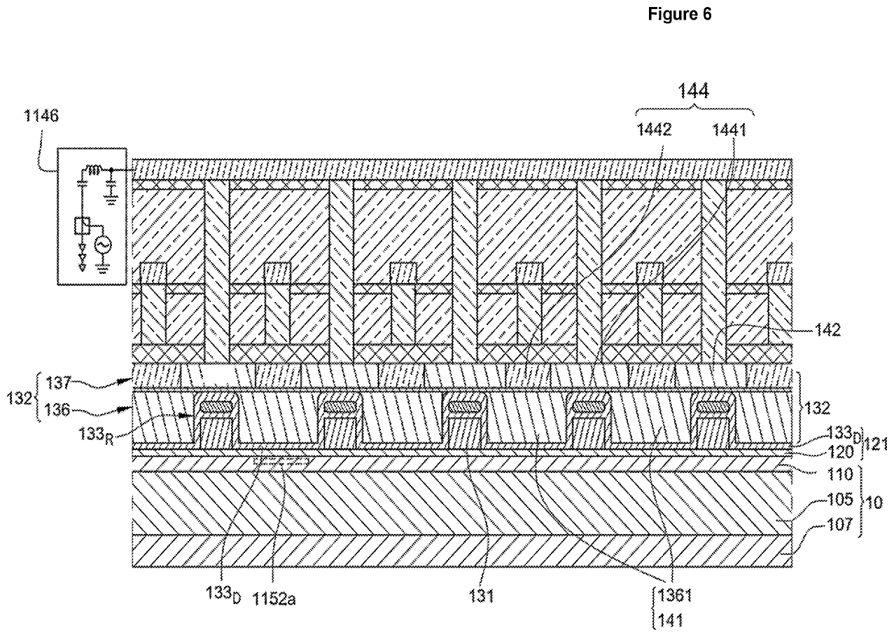

FIGS. 5 to 6 show different views of a second alternative embodiment of the quantum device 100 represented in FIG. 1.

With reference to FIG. 1, and in common with the two alternative embodiments illustrated in FIGS. 2 to 4 and FIGS. 5 to 6, the quantum device 100 extends in a {X, Y} plane and is formed from a semiconductor layer 110. The device 100 further comprises a dielectric 121, first and second gates 131, 132 and charge detectors 140. The first gates and the second gates are typically coupling gates.

These elements are described in detail hereinafter.

In the remainder of the description, the terms “thickness” or “height” designate dimensions measured perpendicularly to the {X; Y} plane. The term “lateral dimension” designates a dimension measured in the {X; Y} plane.

It is noted that the wording “gate” can be used to herein designate a line of gates. By “line of gates” is understood a line comprising a plurality of gates.

Furthermore, in the following, the gates overcoming an area between two quantum dots are gates controlling the potential barrier between the two considered quantum dots.

The semiconductor layer 110 has a front face 110a, illustrated in FIG. 2.

The semiconductor layer 110 is adapted to form an array 115 of quantum dots. In other words, the semiconductor layer 110 has characteristics for forming an array 115 of quantum dots 1151 therewithin. These quantum dots are represented by hatched circles in FIG. 1.

The term “array” here designates an arrangement of quantum dots in rows 115a and columns 115b.

With reference to FIG. 2 or FIG. 6, the semiconductor layer 110 has a thickness of between 5 nm and 35 nm and preferably between 10 nm and 20 nm, for example 15 nm.

The semiconductor layer 110 is preferably a silicon layer 110.

Preferably, this silicon layer 110 comes from a Silicon On Insulator (SOI) substrate 10.

Such a substrate 10 is especially illustrated in FIG. 2. It comprises a stack, from bottom to top, of a bulk semiconductor layer 105, an insulating layer 107, and the silicon semiconductor layer 110. The insulating layer 107 is disposed between the bulk semiconductor layer 105 and the semiconductor layer 110. Polarizing such a substrate 10 allows electrostatic control of charge confinements in the semiconductor layer 110.

Alternatively, the semiconductor layer 110 can be a bulk silicon layer.

The semiconductor layer 110 can, alternatively, be a semiconductor heterostructure comprising a quantum well or a two-dimensional electron gas (2DEG). Such structures have interfaces with low defect densities, facilitating charge confinement and electrostatic control.

The semiconductor layer 110 can advantageously have holes 117. These holes 117 are illustrated by white circles in FIG. 1. These holes 117 can be obtained, for example, by etching the semiconductor layer 110.

The holes 117 are preferably arranged in rows and columns to form an array of holes 117. In FIG. 1, the rows of holes 117 are oriented in a first direction X corresponding to the direction of the rows 115a of quantum dots 1151. Similarly, the columns of holes 117 are oriented in a second direction Y corresponding to the direction of the columns 115b of quantum dots 1151.

The holes 117 are disposed between the rows and columns of quantum dots. Preferably, as illustrated in FIG. 1, four holes 115 flank each zone corresponding to a quantum dot 1151.

The diameter of the holes 117 is preferably between 20 nm and 50 nm. Thus, the holes 117 structure the semiconductor layer 110 to confine charges in each non-etched zone, i.e. in the zone corresponding to the quantum dot 1151. The presence of holes 117 thus facilitates formation of quantum dots 1151.

The dielectric 121 is disposed on the front face 110a of the semiconductor layer 110 and is formed of one or more layers, each layer being formed of a dielectric material (see FIG. 2, or FIG. 6).

According to one alternative, represented in FIG. 9, the dielectric 121 consists of a single layer 120 of dielectric which covers the front face 110a of the semiconductor layer 110. The dielectric layer 120 is preferably between 5 nm and 10 nm thick and is electrically insulating. The dielectric layer 120 is for example of silicon oxide (SiO₂).

According to another alternative, illustrated in FIG. 2 and FIG. 6, the dielectric layer 120 is covered, between the first gates 131, with another dielectric layer, referred to as a spacer layer 133 (in FIG. 2, these portions of spacer layer 133 disposed on the dielectric layer 120 are noted as 133D). In this configuration, the dielectric 121 is the stack consisting of the dielectric layer 120 and the spacer layer 133D disposed on this dielectric layer 120. This alternative embodiment is easier to perform than the alternative in which the dielectric 121 consists of the dielectric layer 120 only. Indeed, it is not necessary to structure the spacer layer 133 once it has been deposited onto the first gates 131 and the dielectric layer 120. This alternative therefore makes it possible to dispense with a step of anisotropically etching the spacer layer 133 after it has been deposited (since this etching is not necessary). On the other hand, as will be better understood later, the second gates 132 are a little further away from the semiconductor layer 110 and therefore from the quantum dots 1151. Electrostatic control of the quantum dots as well as coupling of the charge detectors 140 to the quantum dots 1151 may thus have substantially lower performance.

The spacer layer 133 is formed of a dielectric material. This material is, for example, SiO₂ or aluminium oxide (Al₂O₃).

The spacer layer 133 has a maximum thickness which depends on the material selected: when the material is SiO₂, the maximum thickness is, for example, 5 nm; when the material is Al₂O₃, the maximum thickness may be between 10 nm and 15 nm.

The first gates 131 and the second gates 132 are conductive strips formed from a conductive material selected from the following materials: doped crystalline silicon (or doped Poly-Si), tungsten (W), titanium nitride (TiN).

The first gates 131 extend entirely over the dielectric 121 (precisely, they extend directly over the dielectric layer 120, which therefore constitutes a gate dielectric), along a first direction X, illustrated in FIG. 1, which corresponds to the orientation of the rows 115a of quantum dots 1151.

Each first gate 131 has a cross-section whose height is preferably between 5 nm and 50 nm, and preferably equal to 25 nm. The lateral dimension and the height of the cross-section are preferably substantially identical. The cross-section of each first gate 131 is then a square cross-section.

Each first gate 131 is further covered, or coated, on its flanks (i.e. its lateral faces) and its upper face (i.e. the face opposite to the dielectric layer 120) with the spacer layer 133 (see FIG. 2).

The spacer layer 133 avoids electrical contact between the first gates 131 and the second gates 132, or more generally between the first gates 131 and higher gate levels. Thus, these higher gate levels are isolated from each other.

The second gates 132 are oriented along a second direction Y different from the first direction X. This direction Y corresponds to the direction of the columns 115b of quantum dots 1151.

In FIG. 1, the second direction is oriented at 90° relative to the first direction X. Of course, this second direction Y can be oriented at an angle different from 90° relative to the first direction X.

Each second gate 132 extends directly over the dielectric 121 (in the example of FIG. 2, over the spacer layer 133 of the dielectric 121) and intersects the first gates 131 at intersection zones (noted I_{G1,G2} in FIG. 1) according to a “nested” configuration.

This nested configuration is described in detail hereinafter, in connection with FIG. 2.

According to this nested configuration, each second gate 132 has a height which is greater than the height of the first gates 131. Preferably, the height of the second gates 132 is between 20 nm and 50 nm greater than that of the first gates 131. The lateral dimension of the second gates is preferably identical to that of the first gates.

In addition, each second gate 132 extends:
directly over the dielectric 121 between two adjacent first gates (or, in other words, in the inter-first gate spaces), and
on the spacer layer 133 covering the flanks and upper face of the first gates at the intersection zones I_{G1,G2}.

In other words, each second gate 132 passes over, or overlaps, the first gates 131 coated with the spacer layer 133 at the intersection zones I_{G1,G2}. This overlap means that the first gates 131 are not physically intersected at the intersection zones 133.

By virtue of the spacer layer 133 which is interposed between the first gates 131 and the second gates 132, each second gate 132 intersects the first gates 131 without making electrical contact together.

In addition, as the height of the second gates 132 is greater than that of the first gates 131, first gates 131 which are housed under insulating recesses 133_{R} in the second gates 132 are obtained at the intersection zones 133.

These insulating recesses (hereinafter referred to simply as “recesses 133_{R}” in the following) are visible in FIG. 2. Each insulating recess 133_{R} forms an insulating bridge under which a first gate 131 passes.

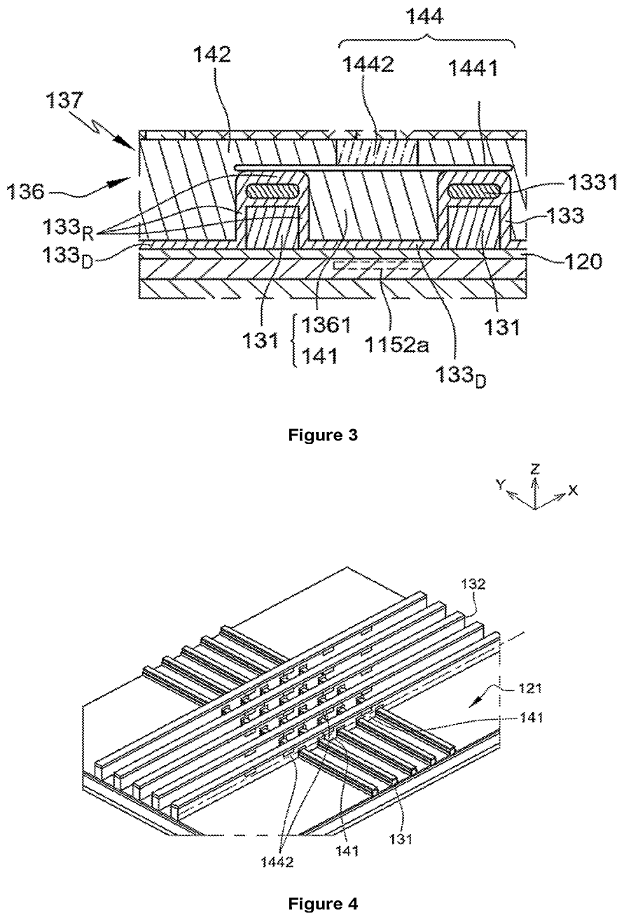

FIG. 3 shows an enlarged view of two consecutive insulating recesses 133_{R}.

The insulating recesses 133_{R} here have a hard mask layer 1331 related to the manufacturing process.

As shown in FIG. 3, the insulating recesses 133_{R} define, in each second gate 132, a lower stage 136 and an upper stage 137 which are conductive.

The lower stage 136 has a pattern comprising a plurality of lower conductive zones 1361 (see FIG. 2).

Each lower conductive region 1361 is separated from adjacent lower conductive zones by one of the insulating recesses 133_{R}.

The upper stage 137 forms a continuous upper conductive region 137. The nested configuration therefore maintains electrical continuity along each first gate 131 and along each second gate 132.

As will be described later in the description, these lower conductive zones 136 and the upper conductive region 137 are advantageously used to form the charge detectors 140.

As shown in FIG. 1, the arrangement of the first and second gates also makes it possible to define a network of regular spaces (hereinafter also referred to as “two-dimensional meshes”) on the surface of the dielectric 121. Each two-dimensional mesh corresponds to the zone of a quantum dot 1151.

Each two-dimensional mesh comprises the free dielectric space defined at the intersection between two adjacent first gates and two adjacent second gates. Each two-dimensional mesh comprises also the closed contour formed by the portions of the gates at the intersection.

In the example of FIG. 1, the directions X, Y of the first and second gates 131, 132 are orthogonal to each other. The two-dimensional meshes are square-shaped.

The directions X, Y of the first and second gates 131, 132 can alternatively be oriented at an angle different from 90°.

When the semiconductor layer 110 includes holes 117 as illustrated in FIG. 1, directions X and Y of the first and second gates also correspond, respectively, to the directions of the rows and columns of holes 117. The first and second gates are also disposed so that there is a hole facing each intersection zone I_{G1,G2}. Thus, a hole 117 is disposed at each apex of the two-dimensional meshes.

Independent control of each first and second gate 131, 132 makes it possible to control electrostatically and with short-range interactions a quantum dot 1151 in each region of the semiconductor layer 110 located in vertical alignment with a two-dimensional mesh.

This control is facilitated by the presence of the holes 117, which enable charges to be confined (non-electrostatically) at the regions of the semiconductor layer forming the quantum dots 1151.

Each region of the semiconductor layer 110 forming a quantum dot has lateral dimensions, defined in the {X, Y} plane, which are preferably between 5 nm and 100 nm, and preferably equal to 50 nm. The thickness of the region of the semiconductor layer 110 forming a quantum dot is moreover preferably between 5 nm and 30 nm, and preferably equal to 15 nm.

The distance between two neighbouring quantum dots, i.e. two quantum dots formed facing two neighbouring two-dimensional meshes, is preferably between 25 nm and 125 nm.

More precisely, control of the first and second gates enables conduction of tunnel barriers 1152a, 1152b located on either side (along directions X and Y) of each quantum dot to be controlled by field effect.

On the part of FIG. 1 representing an enlarged view of a two-dimensional mesh, these tunnel barriers 1152a, 1152b are represented by dotted rectangles. Each tunnel barrier 1152a is located facing a second gate 132 and connects the quantum dot 1151_{i,j} to the adjacent quantum dot 1151_{i-1,j} (or 1151_{i-1,j}) formed on the same row (115a) of the network of two-dimensional meshes. Each tunnel barrier noted 1152b is located facing a first gate 131 and connects the quantum dot 1151_{i,j} to the adjacent quantum dot 1151_{i,j+1} (1151_{i,j-1}) or formed on the same column (115b) of the network of two-dimensional meshes.

The tunnel barriers 1152a, 1152b preferably have lateral dimensions smaller than those of the quantum dots 1151, for example lateral dimensions of between 5 nm and 30 nm. However, their thickness is similar to that of the quantum dots 1151.

According to the above, the first gates 131 are disposed in vertical alignment with first tunnel barriers 1152b, and the second gates are disposed in vertical alignment with second tunnel barriers 1152a. Each first tunnel barrier 1152b connects two neighbouring quantum dots disposed in a same column 115b of the array of quantum dots, while each second tunnel barrier 1152a connects two neighbouring quantum dots disposed in a same row of this array 115.

Each charge detector 140 includes a conductive quantum island 141 (hereinafter also referred to as island 141) and an electrically independent charge reservoir 142.

Each charge detector 140 can be measured by reflectometry.

As shown in FIGS. 2 and 6, the island 141 of each charge detector 140 is formed between two adjacent first gates 131 and directly on the dielectric 121.

Thus, this island 141 is formed at the same level as that of the first and second gates 131, 132. The term “at the same level” means that each island 141 is formed between the lower face of the first gates and the upper face of the second gates. This makes it possible to obtain a compact (in terms of height) quantum device 100. In other words, each island 141 of each charge detector 140 is located in a same horizontal plane than the first lines of gates 131. Similarly, the charge reservoir(s) 142 (i.e., source or drain) of each charge detector 140 is (are) located in a same horizontal plane than the second gates 132, notably in a same horizontal plane than an area of the upper conductive region 137 of the second gates 132.

The island 141 of each charge reservoir 142 of each charge detector 140 can be in a same material than the material of the second gates.

In addition, as will be described later in the description in connection with the manufacturing method, the fact of forming the conductive islands 141 between first gates 131 offers the advantage of being able to use these first gates 131 as an alignment marker at the time of the steps of manufacturing the conductive islands 141. In other words, the first gates enable the islands 141 to “self-align”. This self-alignment facilitates these manufacturing steps.

Compactness and simplicity of manufacture are key advantages for scaling up quantum processors.

In common with the two alternative embodiments illustrated in FIG. 2 and FIG. 5 respectively, each island 141 is formed in one of the lower conductive zones 1361 of a second gate 132. As previously described, these lower conductive zones 1361 are located between two first gates 131.

The island 141 of each charge detector 140 is thus “laid” on the dielectric in vertical alignment with a tunnel barrier 1152a. Each island is thus coupled to both quantum dots 1151 disposed, in the plane of the semiconductor layer 110, on either side of this tunnel barrier 1152a. This coupling is depicted by arrows on the part of FIG. 1 representing an enlarged view of a two-dimensional mesh. Each charge detector 140 is then shared between at least two quantum dots 1151.

Several islands 141 (see FIG. 2) are formed in a same second gate 132.

In this second gate 132, the lower conductive zones 1361 defining an island 141 are covered with a tunnel layer 1441. This tunnel layer 1441 is arranged within the second gate 132. This tunnel layer 1441 has the effect of electrically insulating the island 141 from the upper conductive stage 137 and from the other islands 141 of the second gate 132. It also has the effect of allowing formation of a tunnel current therewithin.

All the charge detectors 140 of this second gate have a common charge reservoir 142, formed at least by the upper stage 137 of this second gate 132. The common charge reservoir 142 is connected by tunnel coupling to each conductive island by virtue of the tunnel layer 1441.

Finally, each charge detector 140 of this second gate 132 includes a gate terminal 144 (the wording “terminal” here being equivalent to the wording gate “contact”), formed by the tunnel layer 1441 and a dielectric pattern referred to as the barrier pattern 1442.

This barrier pattern 1442 passes through the upper conductive region 137 from the tunnel layer 1141 to the upper face of the gate 132. This barrier pattern 1442 is in vertical alignment with part of the conductive island 141. It is also coated with the upper conductive region 137.

Thus, the conductive island 141, the charge reservoir 142 and the gate terminal of each detector 140 are formed in a second gate 132.

The shared use of the second gates 132 makes it possible to reduce overall footprint (lateral and vertical) of the charge detector 140 in the quantum device 100.

The use, in particular, of the upper conductive zone 137 to form/incorporate the charge reservoirs 142, 143 offers an additional advantage for integrating the addressing and reading functions of the charge detectors 140. Indeed, this upper conductive zone 137 is easily accessible for making electrical recontact from above and/or for making electrical recontact at the ends of the second gates.

A structure for controlling the polarization of the gate terminal 144 of each island 141 may thus comprise conductive gate vias 1433 (as hereinafter also referred to as gate vias 1433). As shown in FIG. 2, each gate via 1433 has a lower end disposed on the upper face of the second gate 132, in contact with a barrier pattern 1442.

A structure for reading each island 141 may further comprise one or more read conductive vias 1421 (especially hereinafter referred to as read vias 1421). Each read via 1421 has one end disposed on the upper face of the second gate 132, in contact with the upper conductive region 137. In the example of FIG. 2, several read vias 1421 are arranged on a same second gate 132.

In this case, an encapsulation layer 148 is disposed on the upper face of the second gate to coat the gate vias 1443 and the read vias 1421. This encapsulation layer 148 can be made of a dielectric, for example SiO₂. FIG. 2 shows the presence of a hard mask layer 1332 interposed within the encapsulation layer 148. This hard mask layer 1332 is related to the manufacturing process.

The number of conductive islands 141 formed in the same second gate 132 depends on the inner structure of this second gate 132.

According to the first alternative embodiment, illustrated in FIGS. 1, 2, 3 and 4, the inner structure of the second gate 132 is of a first type for forming an island 141 in every other lower conductive region 1361.

According to this first type of inner structure, and with reference to FIG. 2, every other lower conductive region 1361-1 extends the upper conductive region 137 towards the dielectric 121.

This region 1361-1 defines a complementary lower conductive region 1361-2 (hereinafter also referred to as the complementary lower region 1361-2).

The complementary lower region 1361-2 is covered with a lower barrier layer, referred to as the tunnel layer 1441. This tunnel layer 1441 is disposed on the recesses 133_{R} adjacent to the complementary lower region 1361-2. In other words, the tunnel layer 1441 forms a cover over the complementary lower region, this cover bearing against the adjacent recesses 133_{R}. the barrier layer 1441 is a barrier layer of charges.

Tunnel layer 1441 has characteristics that enable tunnel coupling to be made therewithin.

Tunnel layer 1441 can be formed from aluminium oxide (Al₂O₃).

The tunnel layer 1441 can be formed from silicon oxide (SiO₂). In this case, tunnel layer 1441 has a thickness of between 1 nm and 3 nm.

Preferably, tunnel layer 1441 is formed from hafnium oxide (HfO₂). This material indeed has a programmable resistance that can be adjusted to a value of between a few kiloohms and a few tens of kiloohms. The tunnel layer 1441 is preferably between 5 nm and 10 nm thick.

The tunnel layer 1441 enables an island 141 to be defined in the complementary lower region 1361-2.

The upper stage 137 and the lower conductive region 1361-1 which extends to this upper stage 137 form the charge reservoir 142 of the island 141 formed in the complementary lower region 1361-1. Tunnel coupling between this charge reservoir 143 and the islands 141 is performed in the tunnel layer 1441.

The first type of inner structure also provides that a barrier pattern 1442 forming an upper barrier layer 1442 extends through the upper conductive region 137 from the tunnel layer 1441 to the upper face of the second gate 132.

This barrier pattern 1442 is coated with the upper conductive region 137. Thus, the upper conductive region 137 remains continuous along the second gate 132. The barrier pattern 1442 is disposed in vertical alignment with at least part of the complementary lower conductive region 1361-2.

The barrier pattern 1442 is formed of a material similar to that forming the tunnel layer 1441. In this way, it is adapted to perform tunnel coupling therewithin. The barrier pattern is preferably formed from a material selected from the following materials: SiO₂, Al₂O₃, HfO₂.

Together with the corresponding portion of the tunnel layer 1441, the barrier pattern 1442 forms the gate terminal 144 of the island 141 formed in the complementary lower region 1361-2. The barrier pattern 1442 is a barrier pattern of charges.

As shown in FIG. 4, each second gate 132 may have this first type structure. Alternatively, a second gate 132 may have this first type structure.

The lower conductive regions 1361-2 selected to define the islands 141 in a given second gate 132 are preferentially offset relative to those selected for a neighbouring second gate 132.

In this way, and with reference to FIG. 1, the islands 141 are arranged staggered relative to each other in the assembly formed by the second gates 132. Consequently, the charge detectors 140 are also disposed staggered relative to each other. This staggered arrangement ensures good measurement sensitivity with a reduced number of charge detectors 140.

Returning to FIG. 2, the structure for controlling bias of the gate terminals 144 preferably comprises metallisation rows, referred to as read rows 1445, which are coupled to an LC reflectometry circuit 1446. Each read row 1445 is electrically connected to the read vias 1421 disposed on a same second gate 132.

Each read row 1145 can couple conductive portions 137 located on a same row 115a of the array 115 of quantum dots 1151.

Alternatively, each read row 1145 can couple conductive portions 137 located on the same diagonal 115c of the array 115 of quantum dots 1151.

In addition, the structure for controlling bias of the gate terminals 144 may comprise metallisation rows 1444, referred to as gate rows 1444, coupled to a voltage source. Each gate row 1444 is preferably connected to the gate vias 1443 disposed on a same row of the array 115 of quantum dots.

By combining the structures for reading and controlling the gate terminals, the load detectors 140 can be read individually.

According to the second alternative embodiment, illustrated in FIGS. 5 and 6, the inner structure of the second gate 132 is of a second type making it possible to form an island 141 in each lower conductive region 1361. This second type thus makes it possible, compared to the first type, to double the number of charge detectors 140 formed in a same second gate 132. As shown in FIG. 5, there are then as many charge detectors 140 as there are quantum dots 1151.

By thus increasing the number of charge detectors 140, it is possible to measure each quantum dot as close to it as possible. This improves sensitivity of the measurement of the quantum dots.

The second type of inner structure differs from the first type in that all the lower conductive regions 1361 of the second gate 132 are covered with the tunnel layer 1441. The tunnel layer 1441 then extends in the entire plane of the second gate, at the upper face of the recesses 133_{R} of this second gate (see FIG. 6).

On the other hand, there is a barrier pattern 1442 in vertical alignment with each lower conductive region 1361. As in the structure of the first type, the barrier pattern 1442 passes through the upper conductive region 137 to the tunnel layer 1441 and is coated with the upper conductive region 137.

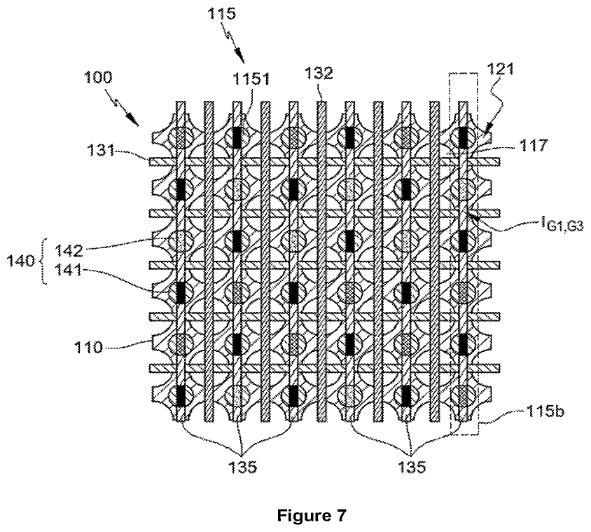

FIGS. 7, 8 and 9 show a second embodiment of the quantum device 100.

The second embodiment differs from the first embodiment, illustrated in FIGS. 1 to 6, in that the charge detectors 140 are not formed in the second gates 132 but in third gates 135 for controlling chemical potential of the quantum dots 1151. The third gates 135 then are charge accumulation gates.

As shown in FIG. 9, the second gates 132 are then covered, on their flanks and upper face, with a layer 133′ of insulating material forming a spacer 133′ similar to the spacer 133. The spacer 133′ thereby makes it possible to electrically insulate these second gates from the third gates 135.

It is noted that in FIG. 9, the dielectric 121 is the dielectric layer 120.

The third gates 135 are conductive strips formed from a conductive material similar to that forming the first and second gates.

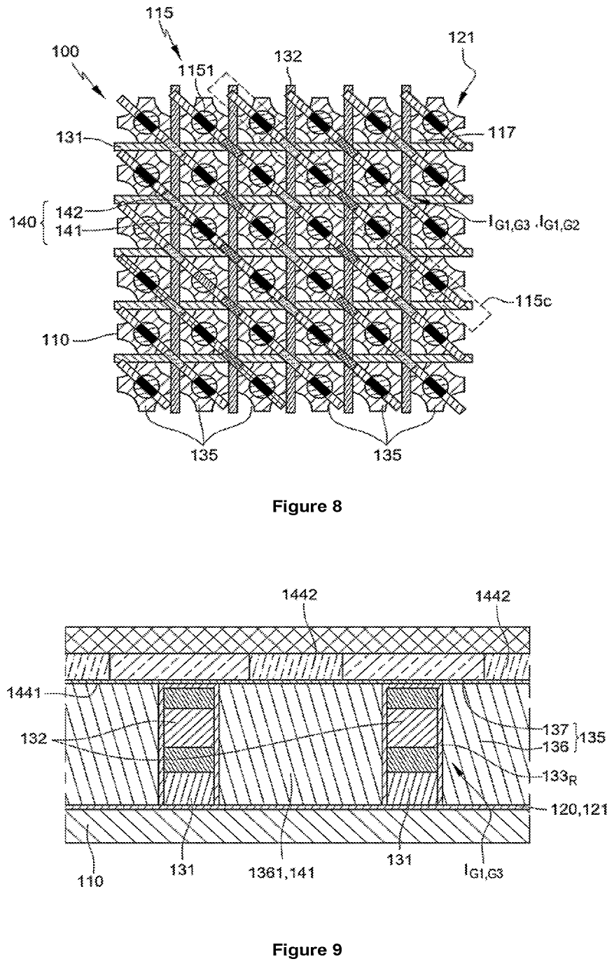

As shown in FIGS. 7 and 8, these third gates 135 are distinct from the second gates 132 and are all oriented in a different direction Y′ from the first direction X of the first gates 131. The third gates 135 and extend in vertical alignment with the quantum dots 1151.

FIG. 7 shows a first alternative embodiment of the second embodiment. According to this first alternative, the third gates 135 are oriented at 90° relative to the first gates 131. In addition, each third gate 135 is disposed between two adjacent second gates, in vertical alignment with the quantum dots disposed on a same column 115b of the array 115 of quantum dots.

The third gates 135 extend directly over the dielectric 121 and intersect the first gates 131 (see FIG. 7) in a nested configuration similar to the nested configuration described previously (in connection with the second gates 132). The intersection zones between the first gates and the third gates are marked with the reference I_{G1,G3} in FIGS. 7 and 8.

FIG. 8 shows a second alternative embodiment of the second embodiment. According to this second alternative, the third gates are oriented at 45° relative to the first and second gates 131, 132. Each third gate 135 extends in vertical alignment with the quantum dots disposed on a same diagonal 115c of the array 115 of quantum dots.

The third gates 135 extend directly over the dielectric 121 and intersect the first and second gates in the same nested configuration as described previously.

The intersection zones between the first and third gates I_{G1,G3} correspond to the intersection zones between the first and second gates I_{G1,G2}.

FIG. 9 schematically shows a cross-section view of a third gate of the device represented in FIG. 8.

As shown in FIG. 9, each third gate 135 extends directly over the dielectric between two adjacent first gates 131 (or, in other words, into inter-first gate spaces), and passes over, or overlaps, the first gates 131 coated with the spacer layer 133 at the intersection zones I_{G1,G3}.

The height of the third gates 135 is greater than that of the second gates 132. Preferably, this height of the third gates is 20 nm to 50 nm greater than that of the second gates 132.

This nested configuration makes it possible to define a two-stage structure (a continuous conductive upper stage 137 and a lower stage formed of a plurality of lower conductive regions 1361) similar to the structure of the second gates 132 illustrated in FIG. 6.

This nested configuration thus makes it possible to form in each third gate 135, or in every other third gate 135, the inner structure previously described in connection with the first embodiment.

In the example shown in FIG. 7, each third gate has the inner structure of the first type, illustrated in FIG. 2.

Thus, in these third gates 135, every other lower conductive region 1361 forms a conductive island 141. In addition, the upper conductive region 137 forms the charge reservoir 142 common to all the islands formed in the third gate 135, and barrier patterns 1442 coated with the upper conductive region 137 form the gate terminals 144 (see FIG. 9).

This configuration enables each conductive island 141 to be positioned in vertical alignment with a quantum dot (unlike the first embodiment, where the islands 141 are in vertical alignment with the tunnel barriers).

This arrangement allows a more localised measurement of the state of charge of the quantum dot 1151 than when the charge detector 140 is located in vertical alignment with a tunnel barrier 1152b. Indeed, a charge detector 140 disposed in vertical alignment with a quantum dot is more sensitive to the same because it is closer than a charge detector disposed in vertical alignment with a tunnel barrier. It is, however, less sensitive to neighbouring quantum dots.

As in the first embodiment, the islands 141 are disposed herein staggered relative to each other.

Of course, the third gates 135 may alternatively have the structure of the second type, illustrated in FIG. 4. In this case, in the third gates 135, each lower conductive region 1361 forms a conductive island 141. A charge detector 140 is then disposed in vertical alignment with each quantum dot 1151.

In the example shown in FIG. 8, each third gate has the inner structure of the second type, illustrated in FIG. 6.

Thus, as in the alternative embodiment illustrated in FIG. 7, each lower conductive region 1361 forms a conductive island 141. In addition, the upper conductive region 137 forms the charge reservoir common to all the islands formed in the third gate, and barrier patterns coated with the upper conductive region form the drains 142.

This configuration makes it possible to position a conductive island 141 in vertical alignment with each quantum dot.

Of course, the third gates may alternatively have the structure of the first type, illustrated in FIG. 2. In this case, in the third gates 135, every other lower conductive region 1361 forms a conductive island 141. A charge detector 140 is then shared between two quantum dots 1151.

From the above, the quantum device 100 comprises two sets of gates for controlling the quantum dots 1151: the first set includes the first gates 131; the second set includes gates that extend directly across the dielectric 120 and intersect the first gates 132. The second set includes, at least, the second gates 132.

In addition, the conductive island 141 of each charge detector 140 is formed by a region of one of the gates of the second set, said region being between two adjacent first gates 131 and disposed directly over the dielectric 121.

In one embodiment, the charge detector 140 can only comprise a single charge reservoir 142, i.e., it comprises only a source or only a drain.

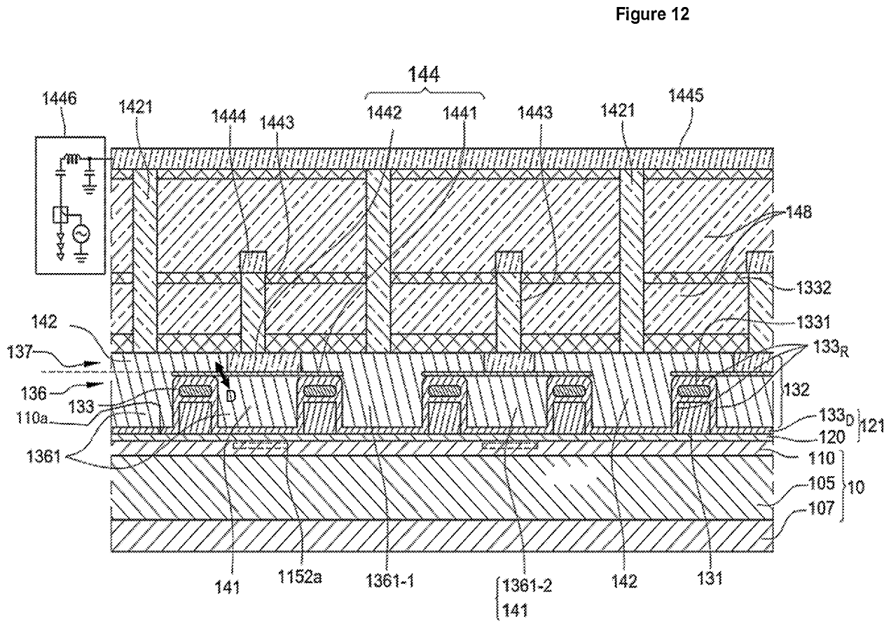

In this embodiment illustrated in FIG. 12, the connection of the island 141 of each charge detector 140, or of a part of them, to the associated charge reservoir 142 can be achieved only on a side of the island 141. Indeed, in relation with FIG. 12, depending on the dimensions (notably the width) of the barrier pattern 1442 and/or depending on the alignment of the tunnel layer 144 with the island 141, it is possible to have a configuration where the connection of the island 141 of the considered charge detector(s) 140 (then of each considered SET) with the upper stage 137 (forming the common charge reservoir 142) is achieved only on one side of the island 141, indicated by the double arrow D on said figure.

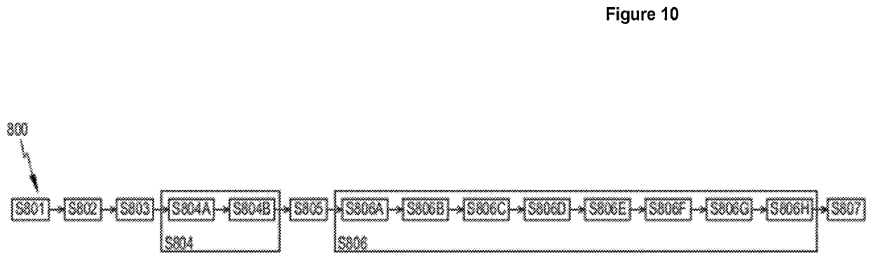

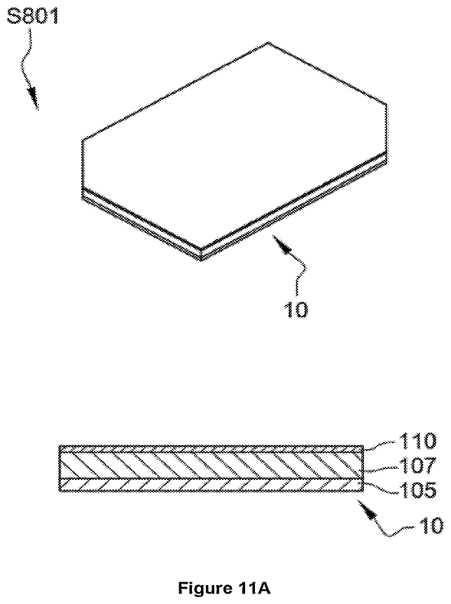

FIG. 10 shows a schematic representation of a block diagram of a method 800 for manufacturing the quantum device 100 illustrated in FIGS. 1 and 2.

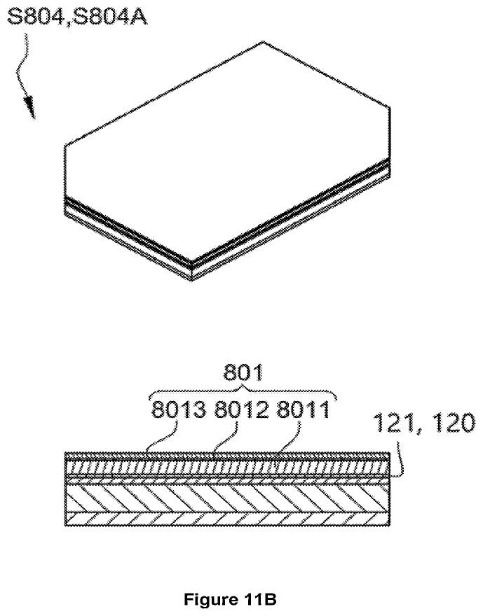

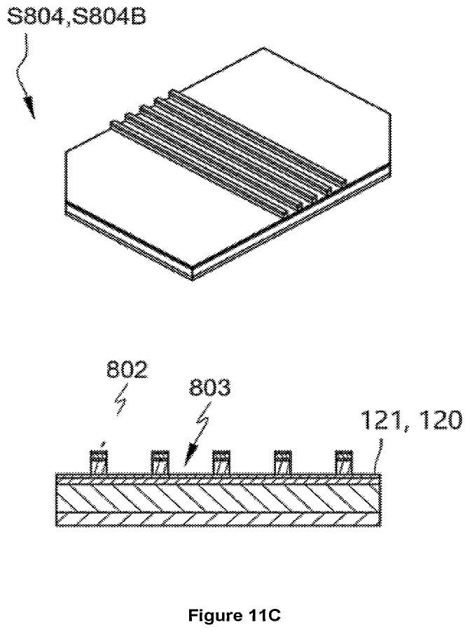

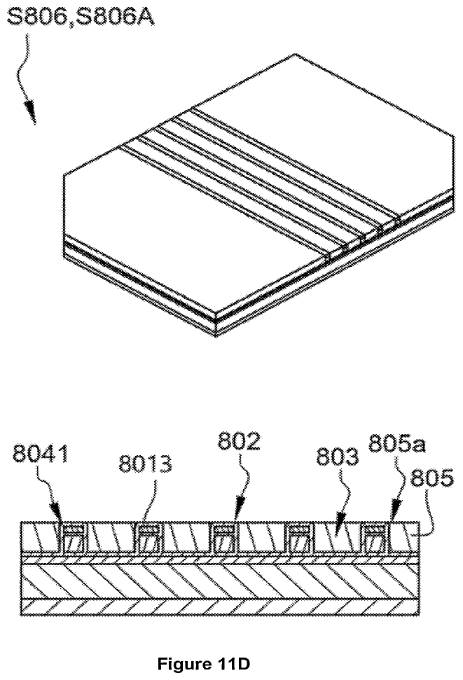

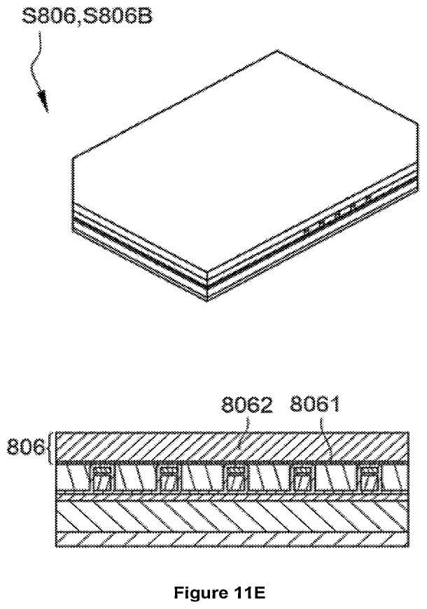

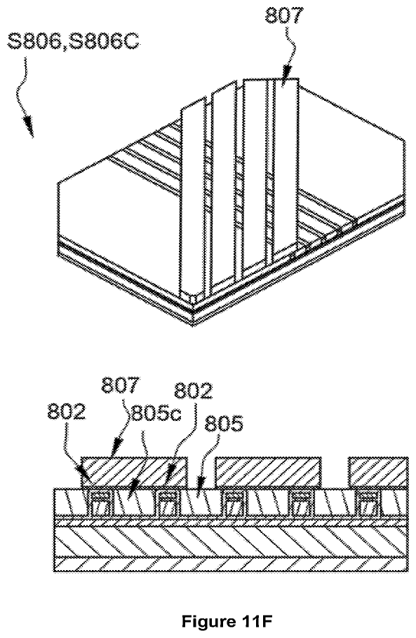

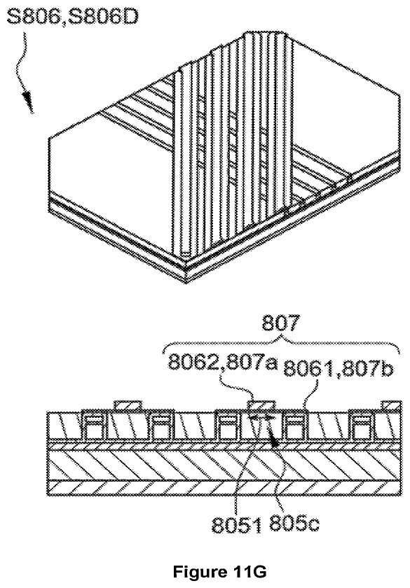

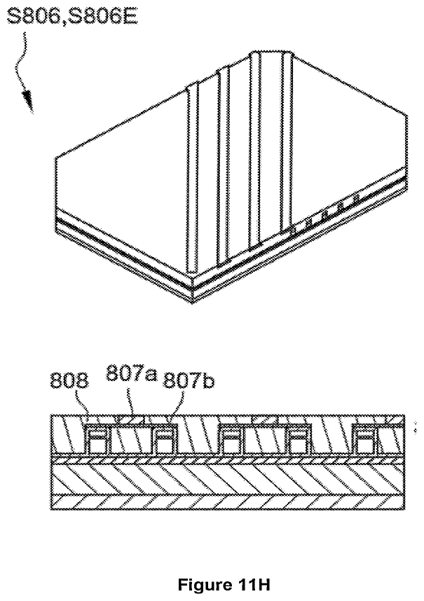

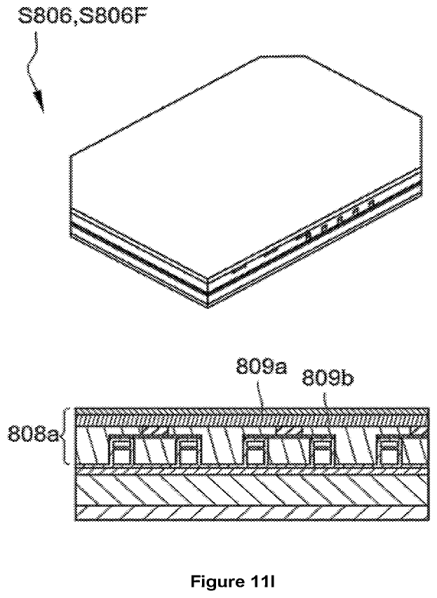

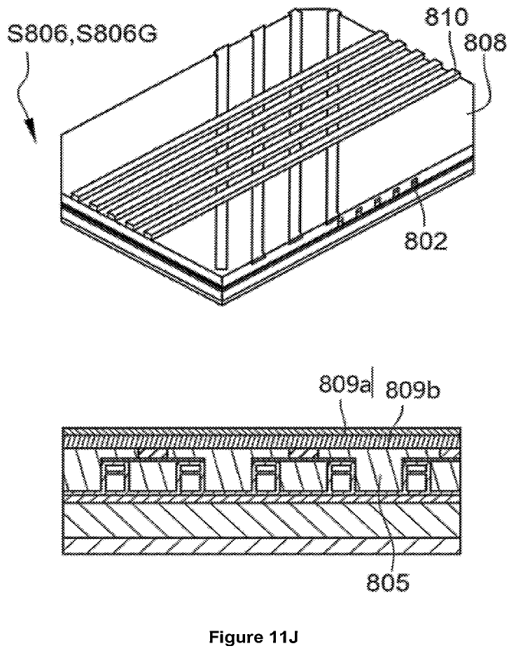

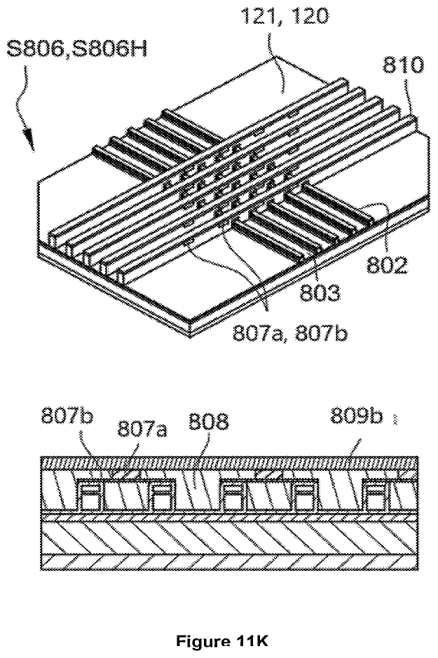

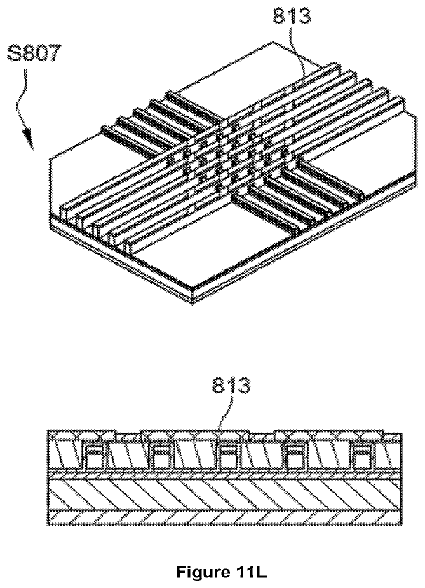

FIGS. 11A to 11L are schematic perspective cross-section views illustrating some steps or sub-steps of the manufacturing method 800.

The manufacturing method 800 begins with a first step S801 of providing the SOI substrate 10 comprising the semiconductor layer 110 on one of its faces. This first step S801 is illustrated in FIG. 11A.

This step S801 is followed by a step S802 (see FIG. 10) of defining the arrangement of the array of quantum dots 115 and the tunnel barriers 1152 in the semiconductor layer 110. In other words, this step S802 consists in determining the regions of the semiconductor layer 110 in which the quantum dots 1151 will be formed, as well as the regions in which the tunnel barriers 1152a, 1152b will be formed.

This step S802 may be followed by a step of etching the semiconductor layer 110 to obtain the holes 117.

The method 800 continues with a step S803 (see FIG. 10) of depositing, onto the entire upper face of the semiconductor layer 110, a first dielectric layer 121 with the material of the dielectric layer 120 of the dielectric 121.

This third step S803 is followed by a fourth step S804 aimed at jointly forming the first gates 131 and the tunnel layer 1441.

With reference to FIG. 10, this step S804 includes the successive sub-steps S804A and S804B. These sub-steps are also illustrated in FIGS. 11B and 11C.

With reference to FIG. 11B, sub-step S804A is a sub-step of forming a first stack 801 over the entire surface of the spacer 120, by:
Depositing, onto the dielectric layer 120, a first conductive layer 8011 of the conductive material of the first gates 131,
Depositing, onto the first conductive layer 8011, a second dielectric layer 8012 of the material forming the spacer 133,
Depositing, onto the second dielectric layer 8012, a first hard mask layer 8013.

Sub-step S804B is a sub-step of three dimensionally structuring the first stack 801 to form first strips 802 parallel to each other, disposed on the dielectric layer 120 facing the first tunnel barriers 1152a defined previously.

The structuring sub-step S804B is carried out by defining an etching mask in the first hard mask layer 8013, and then by successively etching, through the etching mask, the second dielectric layer 8012 and the first conductive layer 8011, with stopping on the dielectric layer 120.

The device obtained at the end of this sub-step S804B is represented in FIG. 11C. As shown in FIG. 11C, the strips 802 obtained are separated by free spaces 803 in the dielectric layer 120.

Step S804 is followed by a fifth step S805 consisting in carrying out conformal deposition of an encapsulation layer 8041 so as to cover the outer limits of the first strips 802 and the free spaces 803. The encapsulation layer 8041 is made from the spacer material 133. This deposition may be followed by planarisation of the encapsulation layer 8041 on the upper faces of the first strips 801.

At the end of this step S805, the insulating recesses 133_{R} of the second gates 132 are prepared.

The method 800 continues with a sixth step S806, the purpose of which is to jointly form the second gates 132 and the islands 141 in these second gates 132.

With reference to FIG. 10, step S806 preferably includes the successive sub-steps S806A, S806B, S806C, S806D, S806E, S806F, S806G and S806H illustrated in FIGS. 11D, 11E, 11F, 11G, 11H, 11I, 11J and 11K respectively.

With reference to FIG. 11D, sub-step S806A consists in forming lower conductive strips 805 by filling the inter-first strip spaces 803 with the conductive material for forming the second gates 132. Filling is carried out up to the level of the encapsulation layer 8041 disposed on the upper face of the first strips 802. This filling is advantageously followed by planarising the conductive layer deposited to leave a planar upper surface 805a level with the first strips 802.

With reference to FIG. 11E, sub-step S806B consists in depositing, onto the entire upper surface 805a formed at the end of step S806A, a stack 806 of barrier layers comprising: a lower barrier layer 8061 formed with the material of the tunnel layer 1441 and an upper barrier layer 8062 formed with the material of the barrier patterns 1442.

Sub-step S806C, which continues sub-step S806B, consists in three dimensionally structuring the stack of dielectric layers 806 to form barrier strips 807. With reference to FIG. 11F, these barrier strips 807 are preferably parallel to each other and oriented at 45° relative to the first strips 801. They are also oriented in a direction X1 perpendicular to the first strips 802. Furthermore, each barrier strip 807 overlaps a lower conductive strip 803 as well as the two adjacent first strips 801.

The orientation of the upper barrier layer strips 807 enables the desired periodicity of the charge detectors 140 in the quantum device 100 to be achieved. Here, the 45° orientation enables periodicity of every other island 141 formed in a bottom conductive region 1361 (i.e. one charge detector 140 for two quantum dots 1151) to be achieved.

The resulting structure is illustrated in FIG. 11F.

These barrier strips 807 define the tunnel layer 1441 and enable the islands 141 to be defined.

The next sub-step S806D consists in anisotropically etching the upper barrier layer 8062 from the barrier strips 807, and with stopping on the lower barrier layer 8061. The final structure is illustrated in FIG. 11G. In each dielectric strip 807 thus structured, the upper barrier layer 8062 forms an upper dielectric strip 807a whose lateral dimensions (along direction X) are smaller than the dimension of the lower conductive strip 805c, and which is positioned in a central zone 8051 of this lower conductive strip 805c. The fourth dielectric layer 8061 forms a lower barrier strip 707b.

Sub-step S806E, illustrated in FIG. 11H, consists in forming an upper conductive layer 808 by depositing the conductive material for forming the second gates 132 onto the entire lower and upper dielectric strips 807a, 807b and up to level with these upper dielectric strips 807a. This sub-step S806E may further comprise an operation of planarising the upper conductive layer 808.

Sub-steps S806F, S806G and S806H aim at three dimensionally structuring the stack 808a formed by the lower conductive strips 805 and the upper conductive layer 808 to form second conductive strips 809 parallel to each other and oriented perpendicularly to the first strips 802, extending over the dielectric layer 120 and intersecting the first strips, forming insulating bridges above these first strips 802.

Sub-step S806F, illustrated in FIG. 11I, consists in forming one or more layers 809a, 809b for forming a hard mask 809 over the entire planarised surface.

Sub-step S806G, illustrated in FIG. 11J, consists in defining an etching mask in the hard mask layer 809, so as to define second strips 810 parallel to each other and oriented perpendicularly with respect to the first strips 802, extending facing the second tunnel barriers 1152b (not represented in FIG. 11J), and each coating a plurality of portions of the barrier layers 807a, 807b.

Sub-step S806H consists in performing selective etching through the hard mask 809, the dielectric strips 807a and 807b structured, the upper conductive strip 808 and the lower conductive strips 805, with stopping at the dielectric layer 120.

The structure thus formed is illustrated in FIG. 11K.

At the end of this sub-step S806H, the second strips 810 are formed. These second strips 810 correspond to the second gates with the charge detectors 140 formed therewithin.

The method for manufacturing may further be continued with a step S807 consisting in removing the hard mask 809 remained on the upper face of the second strips 810, and then performing siliconizing, for example by depositing a layer 813 of SiN onto the second strips 810. FIG. 11L illustrates the quantum device 100 obtained at the end of this step S807.

The manufacturing method just described makes it possible to manufacture the quantum device 100 according to the first embodiment (see FIG. 1).

To make the quantum device 100 according to the second embodiment (see FIG. 7), the steps are identical with the exception of:

Sub-step S806C of structuring the dielectric strips 807 which is modified so that only the upper dielectric layer 8062 is structured, and so that the resulting structure defines dielectric strips which extend not at 45° relative to the first strips, but at 90°. In this way, the dielectric strips define an island in each lower conductive strip,

Sub-step S806D is deleted.

This method of structuring the dielectric strips is advantageous in that it reduces the number of steps required.

1. A quantum device (100) comprising:
a semiconductor layer adapted to form a two-dimensional array of quantum dots, the semiconductor layer having a front face,
a dielectric, disposed on the front face of the semiconductor layer,
first lines of gates and second lines of gates to control the quantum dots, the first lines of gates and the second lines of gates extending directly over the dielectric, each second line of gates intersecting the first lines of gates, the first and second lines of gates defining a network of two-dimensional meshes, each two-dimensional mesh facing a quantum dot, the first and second lines of gates being lines of coupling gates,
charge detectors, each charge detector comprising a conductive charge reservoir and a conductive island,
the conductive island of each charge detector being formed at the level of a two-dimensional mesh, between two adjacent first lines of gates and directly over the dielectric.

2. The quantum device according to claim 1, wherein each charge detector comprises a line of gate contact, said line of gate contact being formed by a charge barrier layer covering the conductive island corresponding to the charge detector.

3. The quantum device according to claim 1, wherein the conductive island of each charge detector is formed in a line of gates for controlling quantum dots distinct from the first lines of gates, said line of gates intersecting the first lines of gates and extending directly over the dielectric, said line of gates having recesses covered with an electrically insulating layer, the insulating recesses being disposed at the intersections of said line of gates with the first lines of gates, each insulating recess accommodating a first line of gates, the insulating recesses defining, in said line of gates, a plurality of lower conductive regions extending directly over the dielectric, and a continuous upper conductive region.

4. The quantum device according to claim 3, wherein said line of gates is one of the second lines of gates.

5. The quantum device according to claim 3, wherein said line of gates is a third line of gates of a set of third lines of gates for controlling chemical potential of the quantum dots, each third line of gates being disposed in vertical alignment with the quantum dots formed along a column or diagonal of the array of quantum dots.

6. The quantum device according to claim 3, wherein said line of gates has an inner structure of a first type comprising:
every other lower conductive region extending from the upper conductive region towards the dielectric and defining a complementary lower conductive region,
the complementary lower conductive region covered with a lower barrier layer, referred to as a tunnel layer, the tunnel layer being disposed on the insulating recesses adjacent to the complementary lower conductive region,
a dielectric pattern forming an upper barrier layer extending through the upper conductive region of the tunnel layer to the upper face of said line of gates, the dielectric pattern being coated with the upper conductive region and disposed in vertical alignment with at least one part of the complementary lower conductive region.

7. The quantum device according to claim 3, wherein the inner structure of said second line of gates is of a second type wherein:
all the lower conductive regions of said line of gates are covered with a tunnel layer, the tunnel layer being continuous and disposed on the recesses of said line of gates,
each lower conductive region has a dielectric pattern there above, each dielectric pattern forming with the tunnel layer a barrier layer, each dielectric pattern passing through the upper conductive region of the tunnel layer disposed on the associated lower conductive region to the upper face of said line of gates, the dielectric pattern being coated with the upper conductive region and disposed in vertical alignment with at least one part of the associated lower conductive region.

8. The quantum device according to claim 3, comprising metallisation rows, referred to as read rows for the charge detectors, each read row being coupled, on the one hand, to the upper conducting region of a line of gates forming conductive islands, and on the other hand to a read circuit, said read circuit comprising an inductance and a capacitance forming a resonant circuit whose resonant frequency depends on the impedance of the charge detectors, allowing reflectometry measurements.

9. The quantum device according to claim 1, wherein the semiconductor layer comprises holes to form the quantum dots.

10. The quantum device according to claim 1, wherein the island of each charge detector is located in a same horizontal plane than the first lines of gates, and the charge reservoir of each charge detector is located in a same horizontal plane than an upper conductive region of the second lines of gates.

11. A method for manufacturing a quantum device comprising charge detectors, each charge detector comprising a conductive island, and a charge reservoir, the method comprising the following steps of:
providing a semiconductor layer adapted to form a two-dimensional array of quantum dots, said semiconductor layer having a front face, said semiconductor layer comprising a dielectric disposed on the front face and first lines of gates to control the quantum dots, the first lines of gates extending directly over the dielectric, the first lines of gates being lines of coupling gates,
coating the flanks and upper face of each first line of gates to house each first line of gates under an insulating recess,
defining the conductive islands from the first coated lines of gates, each conductive island extending between two adjacent first lines of gates and directly over the dielectric,
forming, from the conductive islands defined, second lines of gates to control, with the first lines of gates, the quantum dots, each second line of gates extending directly over the dielectric and intersecting the first lines of gates, the first and second lines of gates forming a network of two-dimensional meshes on the dielectric, the second lines of gates being lines of coupling gates.

12. The manufacturing method according to claim 11, wherein the step of defining the conductive islands comprises the following sub-steps of:
filling, with a conductive material, the spaces of the dielectric which are delimited by two adjacent first lines of gates coated, filling stopping at the height of insulating recesses,
forming a barrier layer over the entire surface obtained after filling,
structuring the barrier layer to form barrier strips oriented at a predetermined angle relative to the first lines of gates.

13. The manufacturing method according to claim 11, wherein the predetermined angle is such that the barrier strips are oriented at 45° relative to the direction of the first lines of gates, the barrier strips extending, in the direction perpendicular to the first lines of gates, over four adjacent conductive strips.
